(19) United States
(12) Patent Application Publication
(10) Pub. No.: US 2024/0215152 A1
(43) Pub. Date: Jun. 27, 2024

(54) SURFACE TENSION DRIVEN FLEXIBLE ELECTRONICS TRANSFER PRINTING METHOD

(71) Applicant: DALIAN UNIVERSITY OF TECHNOLOGY, Dalian, Liaoning (CN)

(72) Inventor: Ming LI, Dalian, Liaoning (CN)

(21) Appl. No.: 18/031,957

(22) PCT Filed: Nov. 14, 2022
(86) PCT No.: PCT/CN2022/131582

§ 371 Date: Apr. 14, 2023

(30) Foreign Application Priority Data
Nov. 19, 2021 (CN) 202111374107.9

(51) Int. Cl. H05K 1/02; H05K 3/00; H05K 3/12; H05K 3/46

(52) U.S. Cl. CPC H05K 1/028; H05K 3/0085; H05K 3/1275; H05K 3/4638; H05K 2203/0766; H05K 2203/14

(57) ABSTRACT

The present invention discloses a surface tension driven flexible electronics transfer printing method which uses a surfactant liquid membrane or a surfactant bubble as a transfer printing stamp, to realize the transfer printing of an electronic device with nanometer/micron/submillimeter thickness. A process of transfer printing is transparent and visible in a “what you see is what you get” manner to realize the accurate positioning of the electronic device. A local load technology is introduced, which is suitable for arbitrary complex curved substrate to realize diverse transfer printing. The electronic device can be transfer-printed to an application substrate with extremely-low interfacial adhesion, without the requirement for the strong and weak adhesion switching strategy of the traditional transfer printing. An unbearable electronic device membrane can be transfer-printed to an fragile receiving substrate with no loss or low loss, without the introduction of pre-pressure.

### TECHNICAL FIELD

The present invention belongs to the technical field of micro nanofabrication and flexible electronics, and particularly relates to a surface tension driven flexible electronic transfer printing method.

### BACKGROUND

The flexible electronics technology means that an organic or inorganic electronic device is fabricated on a flexible substrate so that the flexible electronic device has stretchable and bendable functions, and is widely used in the fields of energy, information and medical treatment, such as flexible electronic display, organic light-emitting diode and electronic skin.

Transfer printing is one of the important approaches for realizing the preparation of flexible electronics. It is a method for transferring an electronic device from a donor (manufacturing) substrate to a receiver (application) substrate, mainly comprises two steps of picking and placing, and involves the strong and weak interfacial adhesion switch. The method has great operation difficulty and is hard to apply to the transfer printing onto any curved surface and the transfer printing of ultra-thin (nano) electronic devices.

Currently, how to reduce the difficulty of transfer printing and realize the transfer printing for any curved surface and ultra-thin devices has become the research focus of the flexible electronic technology. The existing transfer printing methods comprise: conformal additive printing, which uses an elastic balloon as a medium to complete curved surface transfer printing. A dynamic control transfer printing method controls retrieving speed to tune the strong/weak interfacial adhesion to complete transfer printing. A microstructure-assisted transfer printing method controls the contact area of surface microstructure through pressure, so as to modify the adhesion strength.

Sacrificial layer transfer printing uses a sacrificial layer to enhance the stiffness and operability of the electronic device, but it takes a long time to dissolve the sacrificial layer and thermal deformation is mostly involved. Liquid film/droplet wet transfer printing uses a liquid film and a droplet as transfer printing stamps, but it takes time to treat and evaporate liquid film/droplet residues. The liquid film is difficult to locate in an underwater environment. Droplet transfer printing needs to form a liquid bridge, and is mostly suitable for rigid and non-deformable electronic devices. The volume deformability of the droplet is limited, and a large droplet becomes unstable and destroyed, which greatly limits the practical range of droplet transfer printing.

Most of the existing transfer printing methods only complete the planar transfer printing of devices at micron level or above, and the transfer printing process is invisible, which is not helpful for precise alignment. During transfer printing, certain pre-load is exerted to control interfacial adhesion strength, which may damage the devices.

### SUMMARY

In view of the above problems, the present invention proposes a surface tension driven flexible electronic transfer printing method, which uses a surfactant liquid membrane or a surfactant bubble as a stamp, to lift an electronic device with nano/micron/sub-millimeter thickness from a solution or a solid surface. The precise positioning of the electronic device on a substrate can be realized through the transparent characteristic of the surfactant liquid membrane and bubble. A local load technology is introduced to realize non-uniform diverse deformation of the surfactant liquid membrane, to conform to any complex curved substrate. After the electronic device is in contact with an application substrate, the transfer printing can be successfully completed by destroying the surfactant liquid membrane and bubble, independent from the limitation of the interfacial adhesion switchability of the traditional transfer printing, so that the electronic device can be transfer-printed to the substrate with extremely-low interfacial adhesion. The thickness of the surfactant liquid membrane remained on the electronic device after transfer printing is sub-microns, without the need for evaporation treatment of the conventional wet transfer printing, conducive to multiple transfer printing. The surface tension driven flexible electronic transfer printing method does not require pre-load: the electronic device/application substrate experiences low stress, and the unbearable electronic device with nanometer/micron thickness can be transfer-printed to any fragile application substrate. The deformabilities of the surfactant liquid membrane and the surfactant bubble are much better than those of the traditional PDMS elastic stamps, balloons and droplets, and hence the transfer printing range is wide. The surfactant liquid membrane and the surfactant bubble are transparent, the transfer printing is completed in a “what you see is what you get” manner, and precise positioning and placement can be easily realized. The method has simple overall process and good process universality, and is suitable for many transfer printing materials and substrate morphologies.

To achieve the above purpose, the present invention adopts the following technical solution:

A surface tension driven flexible electronic transfer printing method comprises the following steps:
(1) Preliminary fabrication of a flexible electronic device with nano/micron/sub-millimeter thickness: preparing the flexible electronic device with nano/micron/sub-millimeter thickness and high accuracy through mature micro/nano fabrication processes such as photolithography and etching: replacing rinsing liquid, such as deionized water, with surfactant liquid with surface tension property so that the electronic device is soaked in the surfactant liquid: or placing the prepared flexible electronic device with nano/micron/sub-millimeter thickness on a solid surface, wherein there is only weak van der Waals interactions between the solid surface and flexible electronic device.
(2) Retrieving of flexible electronic device with nano/micron/sub-millimeter thickness: dipping a rigid ring into the surfactant solution beneath the flexible electronic device, a portion of the flexible electronic device is attached to the ring: with the upward lifting of the ring, making the flexible electronic device leave the surfactant solution with the ring, conformably deforming with the newly-formed surfactant membrane with the ring being lifted: or making a surfactant bubble supported by a capillary tube under internal pressure or a deformed surfactant liquid membrane supported by the ring under external wind pressure come into contact with the flexible electronic device on the solid surface so as to lift the flexible electronic device from the solid surface.
(3) Make contact between the flexible electronic device with nano/micron/sub-millimeter thickness and an application substrate: moving the ring or the capillary tube to make the flexible electronic device in the surfactant membrane or surfactant bubble come into contact with the application substrate in a transparent and “what you see is what you get” manner, to facilitate precise positioning and alignment: and meanwhile, exerting local load control to the surfactant liquid membrane for producing non-uniform diverse deformation, to conform arbitrarily complex curved substrate.
(4) Printing of the flexible electronic device with nano/micron/sub-millimeter thickness: destroying the surfactant liquid membrane or surfactant bubble by a super-hydrophobic rod to successfully print the flexible electronic device with nano/micron/sub-millimeter thickness onto the application substrate: realizing transfer printing through the easy-to-burst properties of the surfactant membrane and surfactant bubble, without requirement of interfacial adhesion switchability, so that the electronic device is transfer-printed to the substrate with extremely-low interfacial adhesion.

The above method uses the surfactant liquid membrane or the surfactant bubble as a transfer printing stamp, to realize the transfer printing of the electronic device with nano/micron/sub-millimeter thickness. The transfer printing process is in a transparent and “what you see is what you get” manner, to realize the precise positioning of the electronic devices. A local load technology is introduced, which is suitable for any complex curved substrate to realize diverse transfer printing. The electronic device can be transfer-printed to the application substrate with extremely-low interfacial adhesion, without requirement of the strong/weak adhesion switchability for the conventional transfer printing. An unbearable electronic device membrane can be transfer-printed to an fragile application substrate with no loss or low loss, without requirement of pre-load. The ignorable residues after transfer printing prevents the following evaporation or other processing, which is beneficial for multiple or multi-layer transfer printing. The surfactant liquid membrane and the surfactant bubble have giant deformability and wide transfer printing range. The method has simple overall process and good process universality, and is suitable for many transfer printing materials and substrate materials. The present invention can be smoothly extended to macroscopic large-area flexible electronic transfer printing.

### DESCRIPTION OF DRAWINGS

FIG. 1 is a schematic diagram that an electronic device in the membrane format is freely soaked in viscous liquid:

FIG. 2 is a schematic diagram of lifting an electronic device membrane from surfactant solution through local contact feature between the electronic device and ring:

FIG. 3 is a schematic diagram of a freely spreading electronic device membrane transferred to the surfactant liquid membrane within the ring:

FIG. 4 is a schematic diagram that a ring with an electronic device membrane is close to and aligned with a receiver substrate with a curved surface:

FIG. 5 is a schematic diagram of an electronic device membrane successfully transfer-printed to a receiver substrate with a curved surface:

FIG. 6 is a schematic diagram that an electronic device membrane is transfer-printed to an unbearable bristlegrass top with low adhesion strength:

FIG. 7 is a schematic diagram that an electronic device membrane is transfer-printed to the interior curved surface of a Klein bottle with limited space:

FIG. 8 is a schematic diagram that an electronic device membrane is transfer-printed to a complex curved surface with non-uniform curvatures:

FIG. 9 is a diagram of transfer printing of an ultra-thin electronic device membrane provided by an embodiment 2 of the present application:

FIG. 10 is a schematic diagram of lifting a thick and rigid electronic device from a donor substrate by a surfactant bubble generated by a hollow capillary in an embodiment 3, and at this moment, the thick and rigid electronic device is not deformed and the surfactant bubble has a morphology with an convex liquid bridge:

FIG. 11 is a schematic diagram of lifting a thin and flexible electronic device from a donor substrate by a surfactant bubble generated by a hollow capillary in an embodiment 3, and at this moment, the thin and flexible electronic device generates deformation conformal with the surfactant bubble:

FIG. 12 is a schematic diagram of moving down a hollow capillary to make a surfactant bubble and the attached electronic device in conformal contact with a receiving substrate and using a hydrophobic rod to contact and destroy the surfactant bubble and hence the electronic device is successfully transfer printed onto the receiving substrate in an embodiment 3: and at this moment, the electronic device can be either a thick and rigid electronic device or a thin and flexible electronic device:

FIG. 13 is a schematic diagram that a thick and rigid electronic device is transfer-printed to a receiving substrate in an embodiment 3:

FIG. 14 is a schematic diagram that a thin and flexible electronic device is transfer-printed to a receiving substrate in an embodiment 3:

FIG. 15 is a schematic diagram that a hollow capillary, a surfactant liquid membrane in a ring and a thick and rigid electronic device in a donor substrate are aligned in an embodiment 4:

FIG. 16 is a schematic diagram that a hollow capillary, a surfactant liquid membrane in a ring and a thin and flexible electronic device in a donor substrate are aligned in an embodiment 4:

FIG. 17 is a schematic diagram that a hollow capillary is used to apply pressure to a surfactant liquid membrane to make the surfactant liquid membrane deformed and contacted with a thick and rigid electronic device in a donor substrate in an embodiment 4: and at this moment, the surfactant liquid membrane has a morphology with an convex liquid bridge:

FIG. 18 is a schematic diagram that a hollow capillary is used to apply pressure to a surfactant liquid membrane to make the surfactant liquid membrane deformed and contacted with a thin and flexible electronic device in a donor substrate in an embodiment 4; and at this moment, the electronic device and the surfactant liquid membrane deform conformably:

FIG. 19 is a schematic diagram of successfully lifting a thick and rigid electronic device from a donor substrate by a surfactant liquid membrane in an embodiment 4, and at this moment, the thick and rigid electronic device is attached to the surfactant liquid membrane which restores its flat morphology:

FIG. 20 is a schematic diagram of successfully lifting a thin and flexible electronic device from a donor substrate by a surfactant liquid membrane in an embodiment 4, and at this moment, the thin and flexible electronic device is attached to the surfactant liquid membrane which restores its flat morphology:

FIG. 21 is a schematic diagram that a hollow capillary, a ring, a surfactant liquid membrane and a thick and rigid electronic device are moved and aligned with a receiving substrate in an embodiment 4:

FIG. 22 is a schematic diagram that a hollow capillary, a ring, a surfactant liquid membrane and a thin and flexible electronic device are moved and aligned with a receiving substrate in an embodiment 4:

FIG. 23 is a schematic diagram that a hollow capillary is used to apply pressure to a surfactant liquid membrane to deform the surfactant liquid membrane and make a thick and rigid electronic device contact with a receiving substrate in an embodiment 4: and at this moment, the surfactant liquid membrane and the receiving substrate produce contact area far exceeding the boundaries of the electronic device:

FIG. 24 is a schematic diagram that a hollow capillary is used for exerting intensity of pressure to a surfactant liquid membrane to deform the surfactant liquid membrane and make a thin and flexible electronic device contact with a receiving substrate in an embodiment 4: and at this moment, the surfactant liquid membrane and the receiving substrate produce contact area far exceeding the boundaries of the electronic device:

FIG. 25 is a schematic diagram of using a hydrophobic rod to break a surfactant liquid membrane for integrating a thick and rigid electronic device into a receiving substrate in an embodiment 4: and

FIG. 26 is a schematic diagram of using a hydrophobic rod to break a surfactant liquid membrane for integrating a thin and flexible electronic device into a receiving substrate in an embodiment 4.

In the figures: 1 transparent viscous surfactant solution: 2 thin and flexible electronic device membrane: 3 ring: 4 liquid membrane: 5 receiving substrate: 6 thick and rigid electronic device membrane: 7 donor substrate: 8 hollow capillary: 9 surfactant bubble: 10 hydrophobic rod.

### DETAILED DESCRIPTION

Embodiments of the present invention are further described below in combination with the technical solutions and drawings.

Embodiment 1: a surface tension driven transfer printing method for nanoscale flexible electronics
(1) An electronic device membrane 2 is rinsed with deionized water to remove residues and impurities on the electronic device membrane 2, and then transparent viscous surfactant solution 1 is used to make the electronic device membrane 2 soaked in the transparent viscous surfactant solution 1. The transparent viscous surfactant solution is soap solution.
(2) A rigid ring is dipped into the transparent viscous surfactant solution and below the electronic device membrane, so that a portion of the electronic device membrane is attached to the edge of the ring. The electronic device membrane is separated from the transparent surfactant solution along with the ring and is located in a liquid membrane formed when the ring leaves the transparent viscous surfactant solution. The electronic device membrane cannot slip freely in the liquid membrane to ensure subsequent positioning accuracy.
(3) As the ring 3 is lifted, the electronic device membrane 2 leaves the transparent viscous surfactant solution 1 completely and adheres to the liquid membrane 4 in the ring 3 in a wrinkle-free manner.
(4) The ring 3 is close to and aligned with a receiving substrate 5 with arbitrary complex curved surface. Move down the ring and apply a local blowing load to the liquid membrane to make the electronic device membrane 2 in conformal contact with the surface of the receiving substrate 5.
(5) The liquid membrane 4 is naturally broken or artificially destroyed, and the electronic device membrane 2 is in close contact with the receiving substrate 5 to complete the process of transfer printing.

The transfer printing medium is viscous surfactant solution with viscosity and surface tension properties. The thickness of the liquid membrane formed by the medium is at nanometer level. The thickness of an ultra-thin electronic device membrane can be as low as 100 nm or less. The electronic device membrane for transfer printing can have in-situ measurement effects. Surface tension produces low stress during the transfer printing process, and is suitable for transfer printing of ultra-thin material. Transparency makes the transfer printing visible and precise positioning is achieved in a “what you see is what you get” way;

In step (4), the contact mode is natural placement or the application of a local blowing load to form non-uniform deformation of the liquid membrane, so that the electronic device membrane and the receiving surface are in conformal contact.

In step (5), one of the alternative ways to artificially destroy the liquid membrane is to contact the liquid membrane with hydrophobic material or conventional material larger than 2 mm.

The mass of the electronic device membrane capable of transfer printing is in direct proportion to the diameter of the ring. In step (2), the method of successfully lifting and limiting the free-floating of the electronic device membrane in the liquid membrane is that a portion of the electronic device membrane is in contact with the edge of the ring.

The above method can realize nanoscale transfer printing. The electronic device membrane can be transfer-printed to arbitrary curved surface, without the requirement for the strong and weak adhesion switching strategy of the traditional transfer printing. The electronic device membrane can be transfer-printed to an unbearable receiving surface with no loss or low loss, without the introduction of pre-pressure and without harm to both the receiving substrate and the electronic device membrane. The transfer printing medium is small and operation space is large. The electronic device membrane can be transfer-printed to a compact spatial curved surface with limited space. The non-uniform deformation of the liquid membrane under the control of external wind pressure in the process of transfer printing is suitable for the transfer printing of the membrane to a curved surface with non-uniform curvatures to realize diverse transfer printing. The process of transfer printing is transparent and vivid in a “what you see is what you get” manner, which is beneficial for precise positioning. The method with simple process has a good process universality, and is suitable for many transfer printing materials and substrate materials. Liquid membrane residues formed by the viscous liquid may not affect the electromagnetic performance of the electronic device and may not cause performance degradation of the device. The present invention can be smoothly extended to macroscopic size.

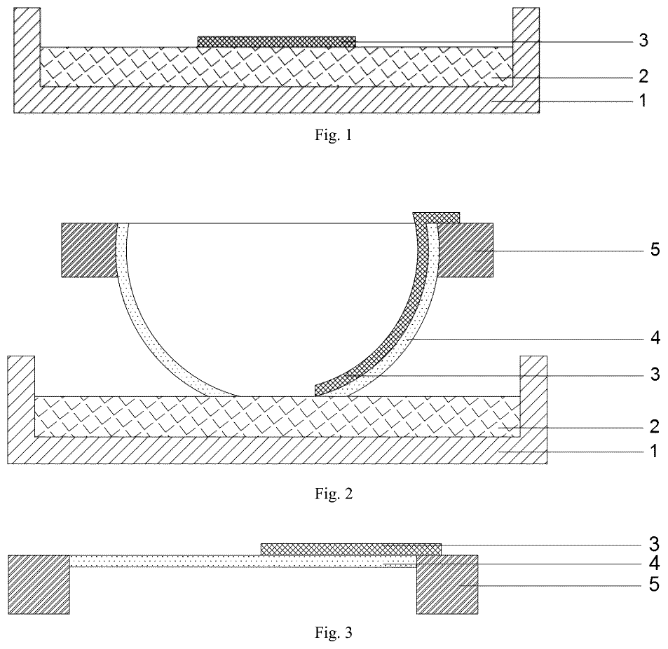

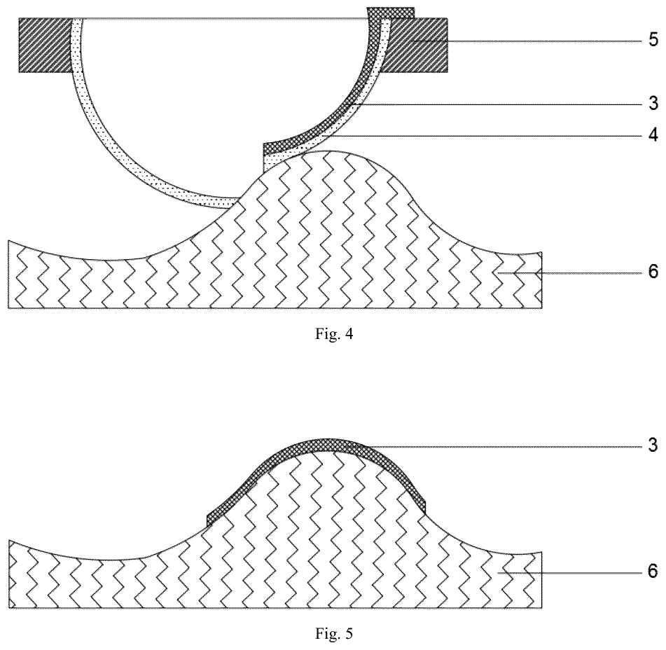

Embodiment 2: a surface tension driven transfer printing method for nanoscale flexible electronics
(1) As shown in FIG. 1, the deionized water for rinsing the electronic device (a 600 nm thick gold membrane with serpentine structures) is replaced by hydrophilic solution with viscosity and surface tension properties. Exemplarily, the used solution may be, but is not limited to, sodium stearate soap solution with a concentration of 3%.
(2) As shown in FIG. 2, a ring with a radius of 5 cm is placed in the soap solution and below the electronic device membrane. A portion of the electronic device membrane is attached to the ring, and the ring is lifted from the soap solution at speed of 1 cm/s. In this process, a soap membrane is formed between the ring and the soap solution surface, and the electronic device membrane is attached to the soap membrane and follows the soap membrane to gradually separate from the soap solution.
(3) As shown in FIG. 3, the ring is lifted continuously until the electronic device membrane is completely separated from the soap solution surface to complete the picking-up process.
(4) As shown in FIG. 4, the ring with the attached electronic device membrane is close to and aligned with the receiving substrate (a school badge model with concave and convex surfaces), and the soap membrane is deformed non-uniformly by fitting the receiving substrate surface directly or applying local wind load. Wind speed is about light breeze, and the distance from the receiving substrate surface is 1 cm, so that the electronic device membrane and the complex surface of the receiving substrate form the global conformal contact.
(5) As shown in FIG. 5, after the electronic device membrane is in contact with the receiving substrate, the soap membrane is naturally broken or artificially destroyed, and the electronic device membrane is finally in close contact with the receiving substrate to complete the process of transfer printing.

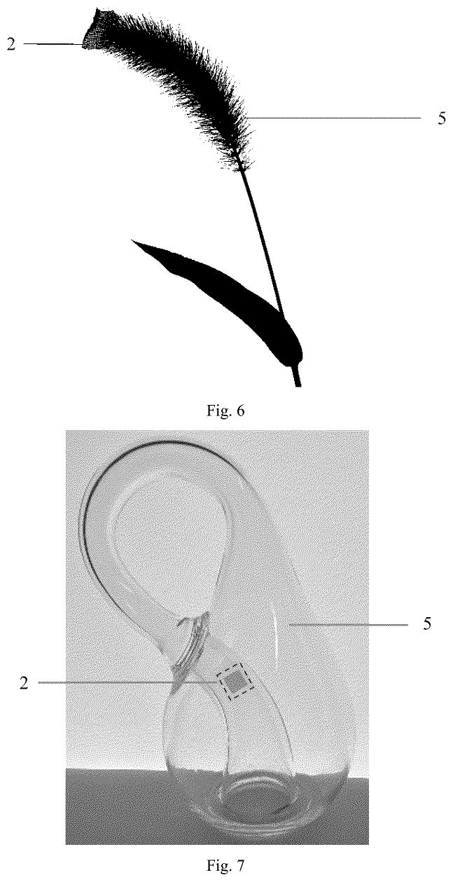

Exemplarily, by referring to FIG. 6, FIG. 6 is a diagram that an electronic device membrane is transfer-printed to an unbearable curved surface with low adhesion strength provided by the present embodiment. In this example, the receiving substrate is top curved surface of a bristlegrass, composed of different microcolumns. The length and width of the patterned structure of the electronic device membrane are both 10 mm, and the thickness is 600 nm. The electronic device membrane can be well transfer-printed to the top curved surface of the bristlegrass.

Exemplarily, by referring to FIG. 7, FIG. 7 is a diagram that an electronic device membrane is transfer-printed to a compact spatial curved surface with limited space, provided by the present embodiment. In this example, the receiving substrate is a slender inner curved wall of a Klein bottle. The length and width of the patterned structure of the electronic device membrane are both 10 mm, and the electronic device membrane can be well transfer-printed to the inner curved wall of the Klein bottle.

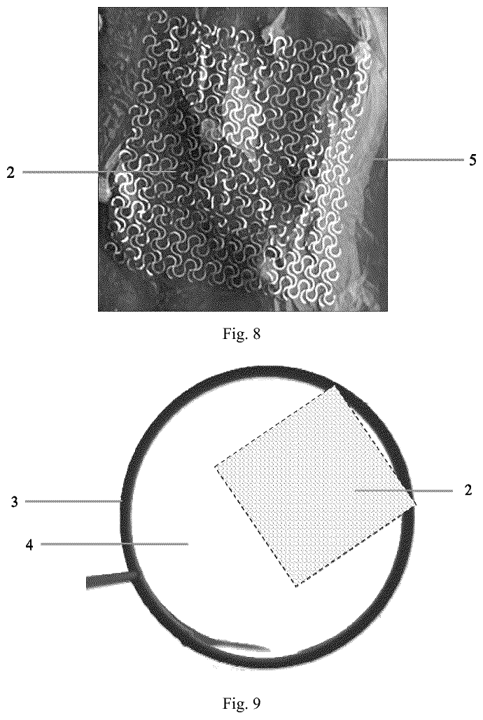

Exemplarily, by referring to FIG. 8, FIG. 8 is a diagram that an electronic device membrane is transfer-printed to a curved surface with non-uniform curvatures, provided by the present embodiment. In this example, the receiving substrates are cucumber surfaces with different curvatures. The length and width of the patterned structure of the electronic device membrane are both 10 mm, and the electronic device membrane can be well transfer-printed and conformably contact to the cucumber surfaces.

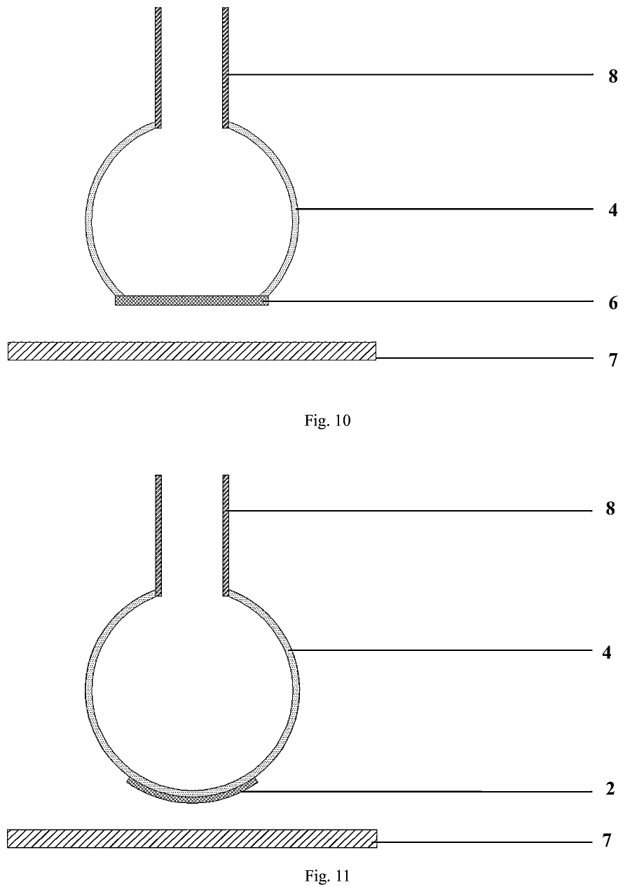

Exemplarily, by referring to FIG. 9, FIG. 9 is a diagram of transfer printing of an ultra-thin electronic device membrane provided by the present embodiment. In this example, the thickness of the electronic device membrane is 100 nm. After lifted from the transparent viscous surfactant solution, the electronic device membrane is freely stretched in the liquid membrane, and the stress/strain level is far below the failure limit.

### Embodiment 3

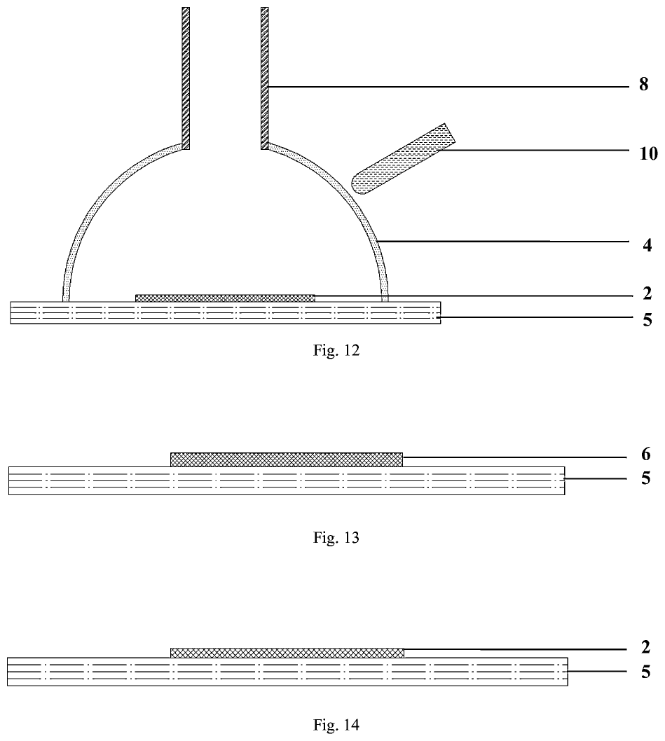

A surface tension driven flexible electronic transfer printing method comprises the following steps:
(1) A hollow capillary 8 is dipped into surfactant solution and then aligned with the electronic device on a donor substrate 7 (solid surface). After blowing gas into the hollow capillary to apply pressure, a surfactant bubble 9 is generated. The surfactant solution is soap solution.
(2) After the surfactant bubble 9 and the electronic device are in conformal contact and a certain contact area is generated, the hollow capillary is lifted upwards to retrieve a thick and rigid electronic device as shown in FIG. 10 and a thin and flexible electronic device as shown in FIG. 11 from a donor substrate. The volume of the surfactant bubble 9 can be reasonably increased to resist the inclining of the electronic device.
(3) The hollow capillary 8 is moved and the electronic device attached to the surfactant bubble 9 is aligned with a receiving substrate. Control the pressure experienced by the surfactant bubble 9, as shown in FIG. 12, yielding the conformal contact between the electronic device and the receiving substrate until the contact area exceeds the boundaries of the electronic device to inhibit the possible flipping of the electronic device. The surfactant bubble/surfactant liquid membrane are artificially destroyed, and a thick and rigid electronic device as shown in FIG. 13 and a thin and flexible electronic device as shown in FIG. 14 are integrated onto the receiving substrate to complete the process of transfer printing.

The electronic device applicable to transfer printing can be either the thick and rigid electronic device or the thin and flexible electronic device. The thick and rigid electronic device refers to an electronic device of submillimeter and micron scales. The thin and flexible electronic device refers to an electronic device of sub-micron and nano scales.

The transfer printing medium is the surfactant bubble formed by the surfactant solution with viscosity and surface tension properties. The thickness is as low as sub-micron and nano scales. There are fewer residues after transfer printing. The electronic device conformably contacts with the receiving substrate, leading to in-situ measurement effects. The surfactant bubble is transparent so that the transfer printing is visible in a “what you see is what you get” manner, so as to realize precise positioning.

In steps (2) and (3), the operation method is to control the pressure of gas on the surfactant bubble and tune the volume of the surfactant bubble, which can effectively inhibit the inclining of the electronic device during the transfer process and the flipping of the electronic device during the printing process.

In step (3), one of the alternative ways to artificially destroy the surfactant bubble is to contact the surfactant bubble with hydrophobic material or conventional material larger than 2 mm.

The cross-section or morphology of the hollow capillary is preferably the morphological feature of the electronic device and can be scaled appropriately, yielding the effect of self-alignment and self-correction of the electronic device during transfer printing, and the alignment accuracy can be effectively improved.

The method can realize the transfer printing of either the thick (submillimeter and micron) and rigid electronic device or the thin (submicron and nano) and flexible electronic device. The electronic device can be transfer-printed to arbitrary complex curved surface with extremely-low interfacial adhesion, without the requirement for the strong and weak adhesion switching strategy of the traditional transfer printing. The electronic device can be transfer-printed to an unbearable receiving surface with no loss or low loss, without the introduction of pre-pressure, with less contact stress and without harm to the receiving substrate and the electronic device membrane. In application in the nano ultra-thin electronic device, large-area transfer printing of the electronic device can be supported. The surfactant bubble can freely match the complex curved surface and bevel, which is suitable for the transfer printing of the electronic device onto a curved surface with non-uniform curvatures and bevel to realize diverse transfer printing. The process of transfer printing is transparent and visible in a “what you see is what you get” manner, which is beneficial for precise positioning. The method with simple process has good process universality, and is suitable for many transfer printing materials and substrate materials. Liquid membrane residues formed by the surfactant solution may not affect the electromagnetic performance of the electronic device and may not cause performance degradation of the device.

### Embodiment 4

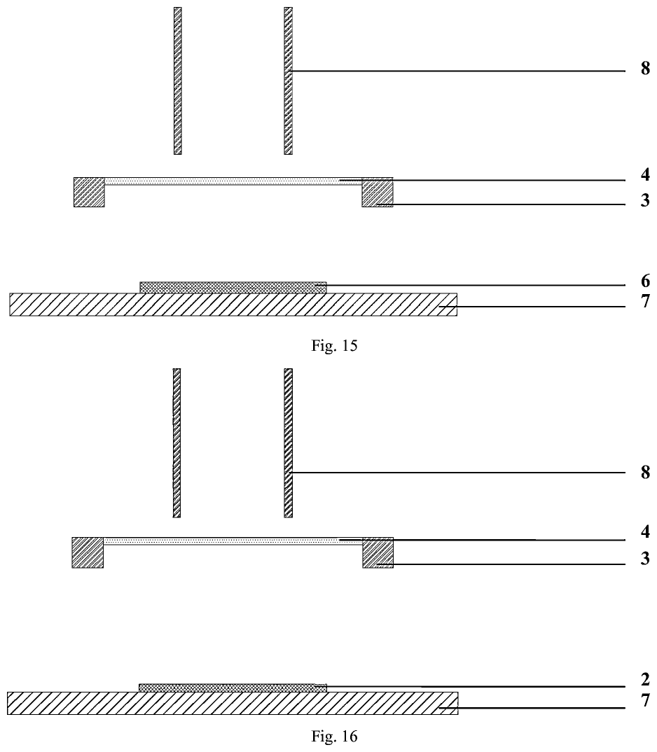

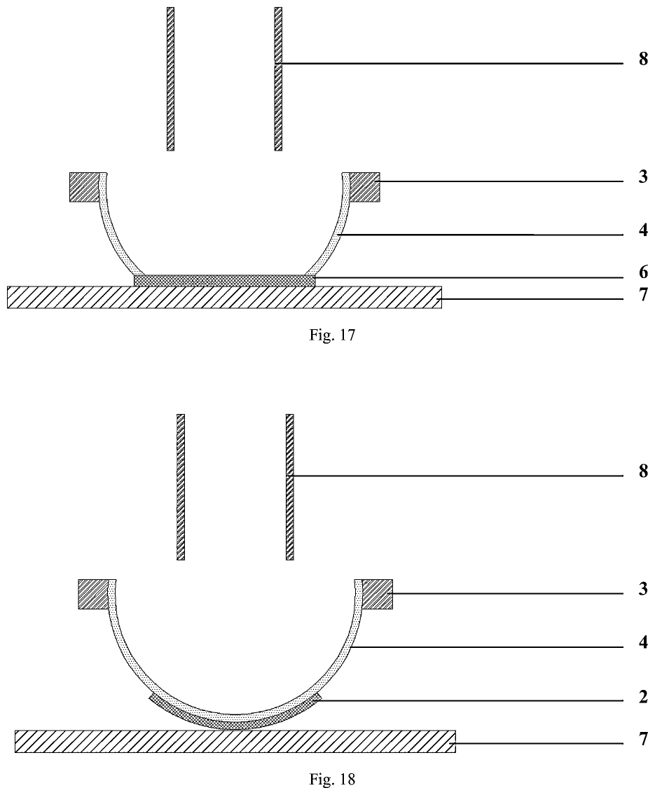

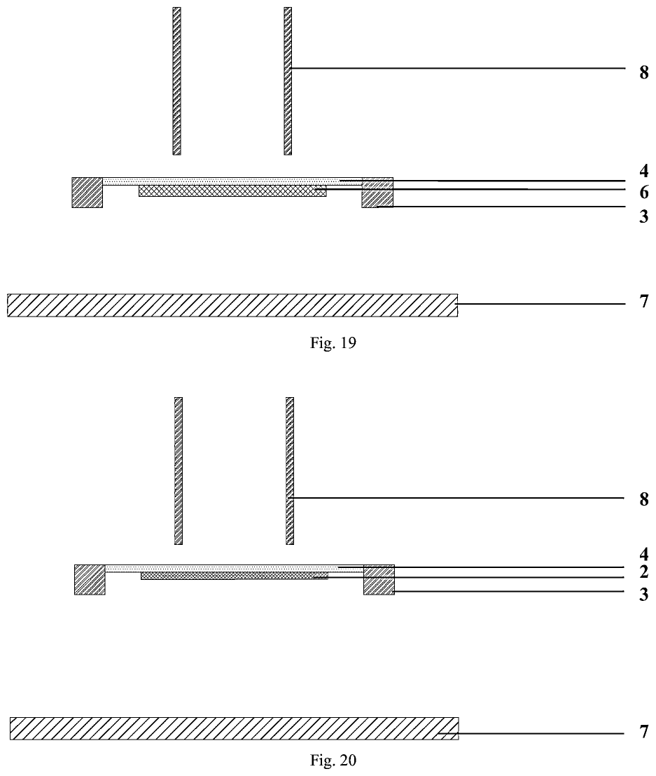

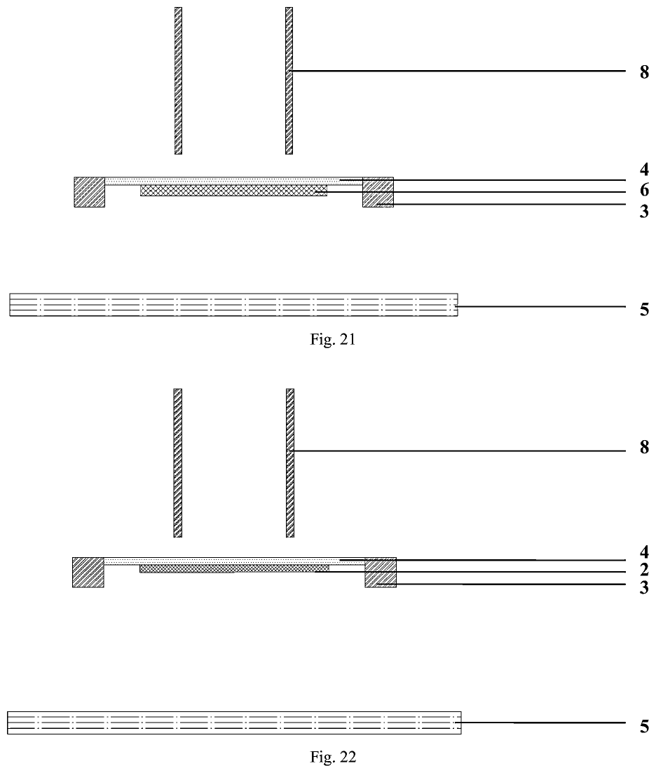

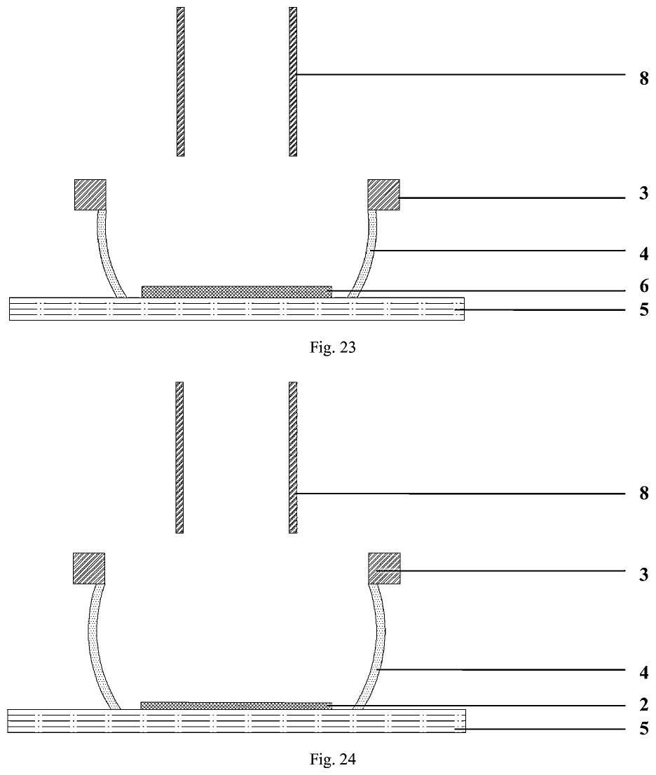

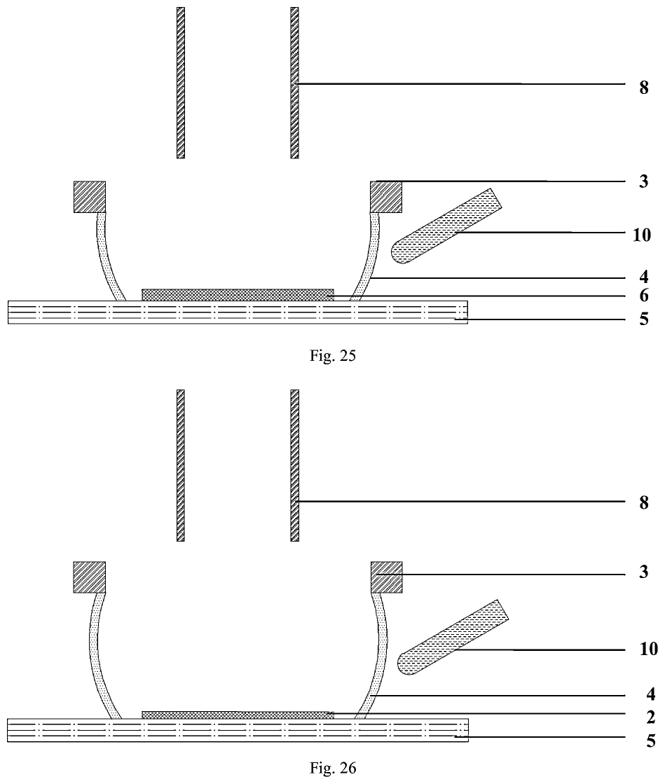

A surface tension driven flexible electronic transfer printing method comprises the following steps:
(1) A ring is dipped into surfactant solution and separated from the surfactant solution. A surfactant liquid membrane is generated within the ring. The ring is moved to align the surfactant liquid membrane with either the thick and rigid electronic device as shown in FIG. 15 or the thin and flexible electronic device as shown in FIG. 16. The surfactant solution is soap solution.
(2) The surfactant liquid membrane is deformed through the controllable local blowing, to lift either a thick and rigid electronic device as shown in FIG. 17 or a thin and flexible electronic device as shown in FIG. 18 through a liquid bridge and conformal deformation.
(3) The thick and rigid electronic device as shown in FIG. 19 and the thin electronic device as shown in FIG. 20 are attached to the surfactant liquid membrane in a tensile and wrinkle-free way.
(4) The thick and rigid electronic device as shown in FIG. 21 and the thin electronic device as shown in FIG. 22 which are attached to the surfactant liquid membrane are aligned with the receiving substrate.
(5) The surfactant liquid membrane is deformed through the controllable local blowing and is in contact with the receiving substrate, and the contact area between the surfactant liquid membrane and the receiving substrate exceeds the boundaries of the thick and rigid electronic device as shown in FIG. 23 and the thin and flexible electronic device as shown in FIG. 24.
(6) A hydrophobic rod 10, etc. is used for destroying the surfactant liquid membrane which supports the thick and rigid electronic device as shown in FIG. 25 and the thin and flexible electronic device as shown in FIG. 26, and the electronic devices are integrated onto the receiving substrate to complete transfer printing.

The electronic device applicable to transfer printing is either the thick and rigid electronic device or the thin and flexible electronic device. The thick and rigid electronic device refers to an electronic device of submillimeter and micron scales. The thin and flexible electronic device refers to an electronic device of sub-micron and nano scales.

The transfer printing medium is the surfactant liquid membrane formed by the surfactant solution with viscosity and surface tension properties. The thickness is as low as sub-micron and nano scales. There are fewer residues after completion of the transfer printing. The electronic device conformably contacts with the receiving substrate, yielding in-situ measurement effects. The surfactant liquid membrane is transparent so that the transfer printing is visible in a “what you see is what you get” manner, so as to realize precise positioning.

In steps (2) and (5), the operation method may be to control the pressure (the magnitude of pressure, the spacing from the nozzle to the surfactant liquid membrane, and the distance from the nozzle to the center of the surfactant liquid membrane) of gas on the surfactant liquid membrane, make the surfactant liquid membrane have non-uniform diverse deformation, and make the electronic device in contact with the receiving substrate, which is suitable for printing of arbitrary complex curved surface.

In step (6), one of the alternative ways to artificially destroy the surfactant bubble is to contact the surfactant bubble with hydrophobic material or conventional material larger than 2 mm.

1. A surface tension driven flexible electronics transfer printing method, comprising the following steps:
(1) preliminary preparation of a flexible electronic device with nanometer/micron/submillimeter thickness: preparing the flexible electronic device with nanometer/micron/submillimeter thickness and high accuracy based on micro and nano processes comprising photolithography and etching, and replacing rinsing solution comprising deionized water, by surfactant solution with surface tension property so that the electronic device is soaked in the surfactant solution; or placing the prepared flexible electronic device with nanometer/micron/submillimeter thickness on a solid surface, wherein there is only weak van der Waals force between solid surface and the flexible electronic device;
(2) retrieving of the flexible electronic device with nanometer/micron/submillimeter thickness: dipping a hard ring into the surfactant solution and below the flexible electronic device, so that a portion of the flexible electronic device is attached to the ring; with the upward lifting of the ring, making the flexible electronic device leave the surfactant solution with the ring; or making a surfactant bubble supported by a capillary under internal pressure or a deformed surfactant liquid membrane supported by the ring under external wind pressure come into contact with the flexible electronic device on the solid surface so as to lift the flexible electronic device from the solid surface;
(3) contact between the flexible electronic device with nanometer/micron/submillimeter thickness and a receiving substrate: moving the ring and the capillary tube to make the flexible electronic device in the surfactant liquid membrane or surfactant bubble come into contact with the receiving substrate in a transparent and “what you see is what you get” manner, to facilitate positioning and alignment; and meanwhile, exerting local load control to the surfactant liquid membrane for producing non-uniform diverse deformation, to conformably contact with arbitrary complex curved substrate;
(4) printing of the flexible electronic device with nanometer/micron/submillimeter thickness: destroying the surfactant liquid membrane or surfactant bubble by a super-hydrophobic rod to successfully print the flexible electronic device with nanometer/micron/submillimeter thickness on the receiving substrate; realizing transfer printing through the easy-to-burst feature of the surfactant liquid membrane or surfactant bubble, without requirement of the interfacial adhesion switchability, so that the electronic device is transfer-printed to the substrate with extremely-low interfacial adhesion.

2. The surface tension driven flexible electronics transfer printing method according to claim 1, wherein a nanoscale flexible electronics transfer printing method comprises the following steps:
(1) rinsing an electronic device membrane with deionized water to remove residues and impurities on the electronic device membrane, and then using transparent viscous surfactant solution with surface tension property to make the electronic device membrane soaked in the viscous surfactant solution;
(2) dipping a ring into the transparent viscous surfactant solution and below the electronic device membrane, so that a portion of the electronic device membrane is attached to the edge of the ring; separating the electronic device membrane from the transparent viscous surfactant solution along with the lifted ring and locating the electronic device membrane in the liquid membrane formed when the ring leaves the transparent viscous surfactant solution; wherein the electronic device membrane cannot slip freely in the liquid membrane to ensure subsequent positioning accuracy;
(3) as the ring is lifted, the electronic device membrane leaves the transparent viscous surfactant solution completely and adheres to the liquid membrane in the ring in a wrinkle-free manner;
(4) making the ring close to and aligned with a receiving substrate with arbitrary complex curved surface; moving down the ring; through natural placement or the application of a local load, forming conformal contact between the electronic device membrane and the surface of the receiving substrate, to form non-uniform deformation of the liquid membrane to make the electronic device membrane in conformal contact with the complex curved surface of the receiving substrate;
(5) naturally breaking or artificially destroying the liquid membrane, and making the electronic device membrane in close contact with the receiving substrate to complete the process of transfer printing;
the transparent viscous surfactant solution is soap solution.

3. The surface tension driven flexible electronics transfer printing method according to claim 2, wherein the thickness of the liquid membrane formed by the transparent viscous surfactant solution is at nanometer level; the thickness of an ultra-thin electronic device membrane can be as low as 100 nm; the printed electronic device membrane can yield in-situ measurement effects; surface tension produces low stress during the transfer printing process, and is suitable for transfer printing of ultra-thin material; transparency makes the transfer printing visible in a “what you see is what you get” manner to achieve precise positioning.

4. The surface tension driven flexible electronics transfer printing method according to claim 2, wherein in step (5), the artificial destroying is to contact the liquid membrane with hydrophobic material or conventional material larger than 2 mm.

5. The surface tension driven flexible electronics transfer printing method according to claim 4, wherein the mass of the electronic device membrane capable of transfer printing is in direct proportion to the diameter of the ring.

6. The surface tension driven flexible electronics transfer printing method according to claim 2, wherein in step (2), the method of successfully lifting and limiting the free-floating of electronic device membrane in the liquid membrane is that a portion of the electronic device membrane is attached to the edge of the ring.

7. The surface tension driven flexible electronics transfer printing method according to claim 4, wherein in step (2), the method of successfully lifting and limiting the free-floating of electronic device membrane in the liquid membrane is that a portion of the electronic device membrane is attached to the edge of the ring.

8. The surface tension driven flexible electronics transfer printing method according to claim 1, comprising the following steps:
(1) dipping a hollow capillary into surfactant solution and then aligning with the electronic device on a donor substrate; after blowing gas into the hollow capillary to form pressure, generating a surfactant bubble; wherein the surfactant solution is soap solution;
(2) after the surfactant bubble and the electronic device are in conformal contact and form contact area, lifting the hollow capillary upwards to drive an electronic device to separate from the donor substrate; appropriately increasing the volume of the surfactant bubble to inhibit the inclining of the electronic device;
(3) moving the hollow capillary and aligning the electronic device attached to the surfactant bubble with a receiving substrate; controlling the magnitude of pressure of gas on the surfactant bubble; making the electronic device and the receiving substrate in conformal contact and form the contact area exceeding the boundaries of the electronic device to inhibit the possible flipping of the electronic device; artificially destroying the surfactant bubble/surfactant liquid membrane, and integrating the electronic device onto the receiving substrate to complete the process of transfer printing;
the electronic device applicable to transfer printing is either the thick and rigid electronic device or the thin and flexible electronic device; the thick and rigid electronic device refers to an electronic device of submillimeter and micron scales; the thin and flexible electronic device refers to an electronic device of sub-micron and nano scales.

9. The surface tension driven flexible electronics transfer printing method according to claim 8, wherein
in steps (2) and (3), the operation method is to control the pressure of gas on the surfactant bubble and tune the volume of the surfactant bubble, to inhibit the inclining of the electronic device during the transfer process and the flipping of the electronic device during the printing process;
in step (3), artificial destroying of the vacuole is to contact the surfactant bubble with hydrophobic material or conventional material larger than 2 mm.

10. The surface tension driven flexible electronics transfer printing method according to claim 1, comprising the following steps:
(1) dipping a ring into surfactant solution and separating from the surfactant solution; generating a surfactant liquid membrane within the ring; moving the ring to align the surfactant liquid membrane with the electronic device; wherein the surfactant solution is soap solution;
(2) deforming the surfactant liquid membrane through the controllable local blowing, to lift the electronic device from the donor substrate through a liquid bridge and conformal deformation;
(3) attaching the electronic device to the surfactant liquid membrane in a wrinkle-free manner;
(4) aligning the electronic device attached to the surfactant liquid membrane with the receiving substrate;
(5) deforming the surfactant liquid membrane through the controllable local blowing, and coming into contact with the receiving substrate, and making the contact area between the surfactant liquid membrane and the receiving substrate exceed the boundaries of the electronic device;
(6) using a hydrophobic rod for destroying the surfactant liquid membrane which supports the electronic device, and integrating the electronic device onto the receiving substrate to complete transfer printing;
the electronic device applicable to transfer printing is either the thick and rigid electronic device or the thin and flexible electronic device; the thick and rigid electronic device refers to an electronic device of submillimeter and micron scales; the thin and flexible electronic device refers to an electronic device of sub-micron and nano scales.

11. The surface tension driven flexible electronics transfer printing method according to claim 10, wherein
in steps (2) and (5), the operation method is to control the pressure of gas on the surfactant liquid membrane, comprising the magnitude of pressure, the spacing from the nozzle to the surfactant liquid membrane, and the distance from the nozzle to the center of the surfactant liquid membrane, make the surfactant liquid membrane have non-uniform diverse deformation, and make the electronic device in contact with the receiving substrate, which is suitable for printing of arbitrary complex curved surface;
in step (6), artificial destroying of the surfactant bubble is to contact the surfactant bubble with hydrophobic material or conventional material larger than 2 mm.
